(19) United States
(12) Patent Application Publication
(10) Pub. No.: US 2025/0241137 A1
(43) Pub. Date: Jul. 24, 2025

(54) CHOKE FILMS FOR OLED STRUCTURES

(71) Applicant: Applied Materials, Inc., Santa Clara, CA (US)

(72) Inventor: Jungmin LEE, Santa Clara, CA (US)

(21) Appl. No.: 18/830,714

(22) Filed: Sep. 11, 2024

Related U.S. Application Data
(60) Provisional application No. 63/623,013, filed on Jan. 19, 2024.

(51) Int. Cl. H10K 59/122; H10K 50/15; H10K 50/17

(52) U.S. Cl. CPC H10K 59/122; H10K 50/156; H10K 50/171

(57) ABSTRACT

Embodiments described herein generally relate to a display. More specifically, embodiments described herein relate to sub-pixel circuits and methods of forming sub-pixel circuits that may be utilized in a display such as an organic light-emitting diode (OLED) display. In one or more embodiments, a sub-pixel includes adjacent overhang structures disposed over a substrate. Each overhang structure has an overhang extension extending laterally past a sidewall of each overhang structure. The sub-pixel further includes a pixel isolation structure (PIS) disposed over the substrate between the adjacent overhang structures. The PIS includes an upper surface and at least two sidewalls opposing each other. An anode is disposed on the PIS. An OLED material is disposed over the anode and extends over the upper surface and the sidewalls of the PIS. The OLED material further extends under the overhang extension. A cathode is disposed over the OLED material.

### CROSS-REFERENCE TO RELATED APPLICATIONS

This application claims priority to U.S. Provisional Patent Application Ser. No. 63/623,013 filed on Jan. 19, 2024 the contents of which are incorporated herein by reference.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Large glass OLED devices can be made to be used in TV applications. However, these large glass OLED devices can be expensive to produce, in large part due to the need to form a local cathode contact for each sub-pixel.

Accordingly, what is needed in the art are sub-pixel circuits and methods of forming sub-pixel circuits having a global cathode contact to decrease the cost of manufacturing.

### SUMMARY

Embodiments described herein generally relate to a display. More specifically, embodiments described herein relate to sub-pixel circuits and methods of forming sub-pixel circuits that may be utilized in a display such as an organic light-emitting diode (OLED) display.

In one or more embodiments, a sub-pixel includes adjacent overhang structures disposed over a substrate. Each overhang structure has an overhang extension extending laterally past a sidewall of each overhang structure. The sub-pixel further includes a pixel isolation structure (PIS) disposed over the substrate between the adjacent overhang structures. The PIS includes an upper surface and at least two sidewalls opposing each other. An anode is disposed on the PIS. An OLED material is disposed over the anode and extends over the upper surface and the sidewalls of the PIS. The OLED material further extends under the overhang extension. The OLED material includes a choked portion having one or more layers. At least one layer of the one or more layers include a continuous region disposed over the anode and the upper surface of the PIS, and a choked region disposed over the sidewalls and extending under the overhang extension. The choked region and the continuous region of the at least one layer are electrically separated from one another. The OLED material further includes a continuous portion disposed over the choked portion. A cathode is disposed over the OLED material.

In one or more embodiments, a sub-pixel includes adjacent overhang structures disposed on a substrate along a line plane. The adjacent overhang structures include a first structure disposed on the substrate and a second structure disposed on the first structure. A bottom surface of the second structure extends laterally past an upper surface of the first structure defining an overhang extension. A pixel isolation structure (PIS) is disposed on the substrate and extends along the line plane in between the adjacent overhang structures. The PIS includes an upper surface and a plurality of sidewalls. An anode is disposed on the PIS. An OLED material is disposed over the anode and extends over the upper surface and the plurality of sidewalls of the PIS. The OLED material further extends under the overhang extension. The OLED material includes a choked portion. The choked portion includes a continuous region disposed over the anode and the upper surface of the PIS, and a choked region disposed over the plurality of sidewalls and extending under the overhang extension. The choked region and the continuous region are electrically separated from one another. The OLED material further includes continuous portion disposed over the choked portion. A cathode is disposed over the OLED material.

In one or more embodiments, a device includes a plurality of sub-pixel lines. Each sub-pixel line includes at least at least one sub-pixel. Each sub-pixel includes adjacent overhang structures disposed on a substrate along a line plane. The adjacent overhang structures include a first structure disposed on the substrate and a second structure disposed on the first structure. A bottom surface of the second structure extends laterally past an upper surface of the first structure defining an overhang extension. A pixel isolation structure (PIS) is disposed on the substrate and extends along the line plane in between the adjacent overhang structures. The PIS includes an upper surface and a plurality of sidewalls. An anode is disposed on the PIS. An OLED material is disposed over the anode and extends over the upper surface and the plurality of sidewalls of the PIS. The OLED material further extends under the overhang extension. The OLED material includes a choked portion. The choked portion includes a continuous region disposed over the anode and the upper surface of the PIS, and a choked region disposed over the plurality of sidewalls and extending under the overhang extension. The choked region and the continuous region are electrically separated from one another. The OLED material further includes continuous portion disposed over the choked portion. A cathode is disposed over the OLED material. An encapsulation layer is disposed over the cathode.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit, according to embodiments.

FIG. 1B is a schematic, cross-sectional view of a sub-pixel circuit, according to embodiments.

FIG. 1C is a schematic, top view of a sub-pixel circuit, according to embodiments.

FIG. 2A is a schematic, cross-sectional view of a portion of a sub-pixel circuit having a single stack structure, according to embodiments.

FIG. 2B is a schematic, cross-sectional view of a sub-pixel circuit having a tandem stack structure according to embodiments.

FIG. 3 is a flow diagram of a method for forming a sub-pixel circuit, according to embodiments.

FIG. 4A-4D are schematic, cross-sectional views of a substrate during a method for forming a sub-pixel circuit, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display.

In one embodiment, a sub-pixel is provided. The sub-pixel includes an anode, overhang structures, an organic light emitting diode (OLED) material, and a cathode. The anode is disposed on an upper surface of a pixel isolation structure (PIS). The overhang structures are disposed between adjacent PIS. The overhang structures include a second structure disposed over the first structure. A bottom surface of the second structure extends laterally past an upper surface of the first structure. Overhangs are defined by an overhang extension of the second structure extending laterally past an upper surface of a first structure. The first structure is disposed over the substrate. The OLED material is disposed over the anode, an upper surface of the PIS, and over the substrate below the overhangs of the overhang structures. The cathode is disposed over the OLED material and an upper surface of the PIS.

Each of the embodiments described herein of the sub-pixel circuit include a plurality of sub-pixels with each of the sub-pixels are defined by adjacent overhang structures that are permanent to the sub-pixel circuit. While the Figures depict two sub-pixels with each sub-pixel defined by adjacent overhang structures, the sub-pixel circuit of the embodiments described herein include a plurality of sub-pixels, such as two or more subpixels. Each sub-pixel has OLED materials configured to emit a white, red, green, blue or other color light when energized. E.g., the OLED materials of a first sub-pixel emits a red light when energized, the OLED materials of a second sub-pixel emits a green light when energized, and the OLED materials of a third sub-pixel emits a blue light when energized.

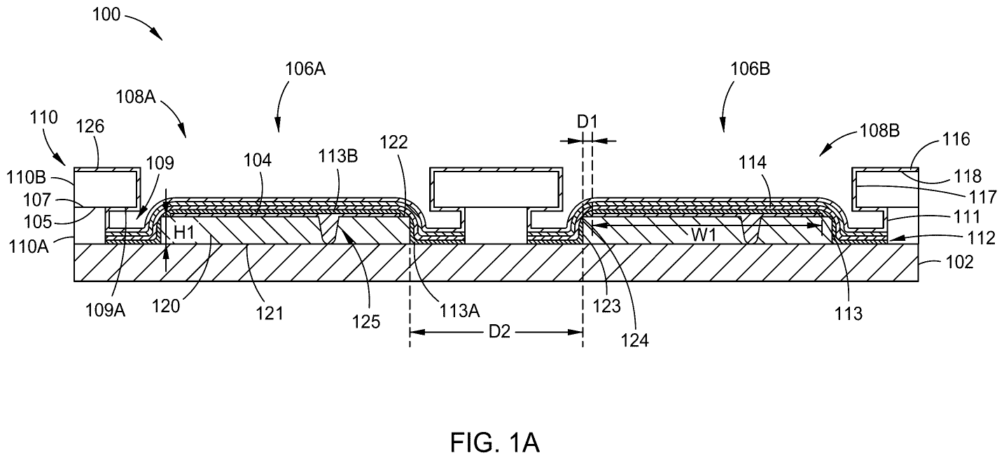

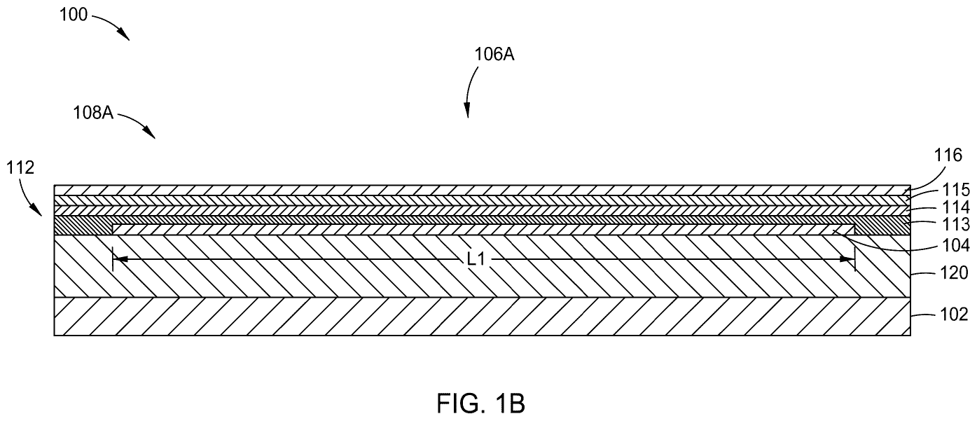

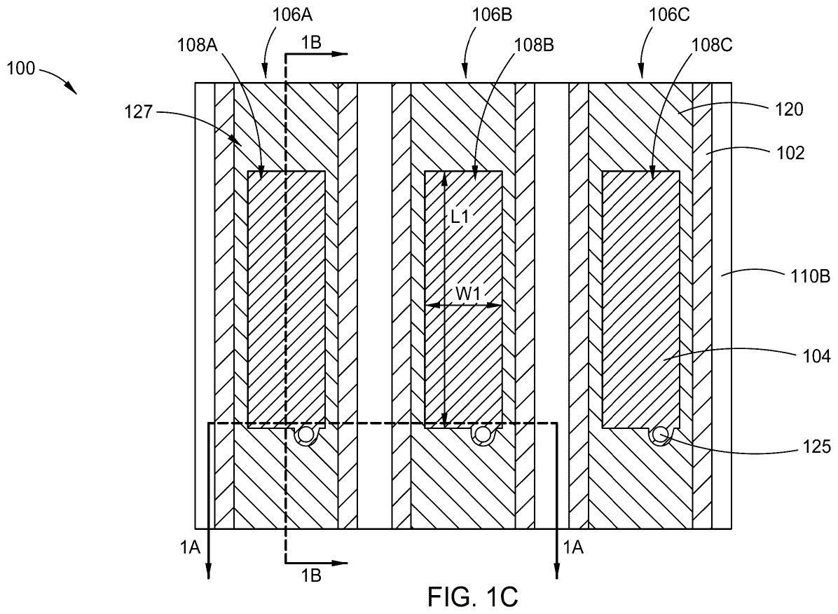

FIG. 1A is a schematic, cross-sectional view of a sub-pixel circuit 100. The cross-sectional view of FIG. 1A is taken along section line 1A-1A of FIG. 1C (e.g., a pixel plane). FIG. 1B is a schematic, cross-sectional view of a sub-pixel circuit 100. The cross-sectional view of FIG. 1B is taken along section line 1B-1B of FIG. 1C (e.g., a line plane). The sub-pixel circuit 100 includes a substrate 102. The substrate 102 is a backplane. The backplane includes, but is not limited to, a complementary metal-oxide-semiconductor (CMOS) array or a thin-film transistor (TFT) array. Pixel isolation structures (PIS) 120 may be patterned on the substrate 102. The PIS 120 extend along the line plane. In one embodiment, the PIS 120 are pre-patterned on the base layer. Each PIS 120 includes at least two sidewalls 123 opposing each other. The PIS 120 have a height H1. The height H1 is defined by a distance between a lower surface 121 of the PIS 120 and an upper surface 122 of the PIS 120. The height H1 is about 200 nm to about 300 nm. The PIS 120 are formed of a material including a metal such as silver (Ag), indium tin oxide (ITO), aluminum polymer composite (APC), aluminum copper alloys (AlCu), titanium nitride (TiN), tin oxide (SnO₂), indium gallium zinc oxide (IGZO), or any combination of the above. The PIS 120 material also include one or more insulation layers in-between the metal material such as silicon nitride (SiNₓ), silicon oxide (SiO₂), or a combination of the above. Each PIS 120 is separated by a distance D2 in the pixel plane. The distance D2 is from about 15 μm to about 30 μm. An anode 104 is deposited on an upper surface 122 of each PIS 120. The anodes 104 are configured to operate as anodes of respective sub-pixels. A distance D1 is defined by the distance between an outer edge of the anode, and a sidewall 123 of the PIS 120. Distance D1 is from about 1 μm to about 2 μm. In one embodiment, the anode 104 is a layer stack of a first transparent conductive oxide (TCO) layer, a second metal-containing layer disposed on the first TCO layer, and a third TCO layer disposed on the second metal-containing layer. The anodes 104 include, but are not limited to, chromium, titanium, gold, silver, copper, aluminum, ITO, a combination thereof, or other suitably conductive materials.

The anode 104 has a width W1 and a length L1. The width W1 of the anode 104 is defined by the distance the anode 104 extends across the PIS 120 in the pixel plane, as shown in FIG. 1A. The width W1 of the anode 104 is from about 10 μm to about 20 μm. The length L1 of the anode 104 is defined by the distance the anode 104 extends across the PIS 120 in the line plane, as shown in FIG. 1B. The length L1 of the anode 104 is from about 110 μm to about 225 μm.

The PIS 120 includes an opening 125. The opening 125 extends from the upper surface 122 to the lower surface 121. The anode 104 is deposited within the opening 125. A portion of the anode 104 contacts the substrate 102 within the opening 125. The portion of the anode 104 within the opening 125 electrically connects the anode 104 to the substrate 102 so that the anode 104 can conduct a current flowing through the substrate 102.

The sub-pixel circuit 100 has a plurality of sub-pixel lines (e.g., first sub-pixel line 106A and second sub-pixel line 106B along a Y-direction). The sub-pixel lines are adjacent to each other along the pixel plane. Each sub-pixel line includes at least one sub-pixel. E.g., the first sub-pixel line 106A includes a first sub-pixel 108A and the second sub-pixel line 106B includes a second sub-pixel 108B. While FIG. 1A depicts the first sub-pixel line 106A and the second sub-pixel line 106B, the sub-pixel circuit 100 of the embodiments described herein may include two or more sub-pixel lines, such as a third sub-pixel line 108C (as shown in FIG. 1C) and a fourth sub-pixel. Each sub-pixel line has OLED materials configured to emit a white, red, green, blue or other color light when energized. E.g., the OLED materials of the first sub-pixel line 106A emits a red light when energized, the OLED materials of the second sub-pixel line 106B emits a green light when energized, the OLED materials of a third sub-pixel line 106C emits a blue light when energized, and the OLED materials of a fourth sub-pixel emits another color light when energized.

Each sub-pixel line includes adjacent overhang structures 110, with adjacent sub-pixel lines sharing the adjacent overhang structures 110 in the pixel plane. The overhang structures 110 are permanent to the sub-pixel circuit 100. The overhang structures 110 further define each sub-pixel line of the sub-pixel circuit 100. Each overhang structure 110 includes adjacent overhangs 109. The adjacent overhangs 109 are defined by an overhang extension 109A of a second structure 110B extending laterally past an upper surface 105 of a first structure 110A. The first structure 110A is disposed over the substrate 102. The first structure 110A is formed of a conductive material. The conductive material includes a metal material such as titanium (Ti), aluminum (Al), magnesium (Mg), or any other metal that can be patterned. The first structure serves as a global cathode contact for the sub-pixel circuit 100. The second structure is formed of an electrically resistive material such as polyimides (PI) or silicon oxide (SiO₂). The overhang structures 110 are able to remain in place, i.e., are permanent.

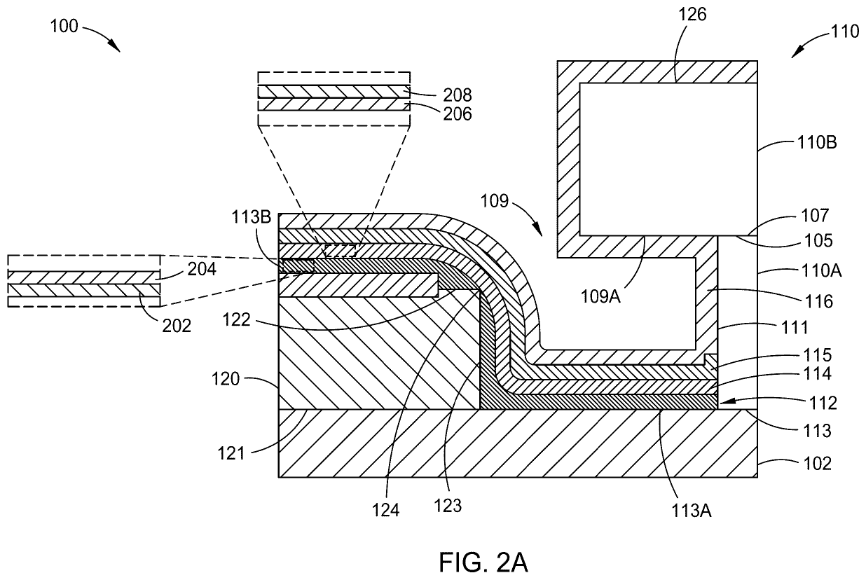

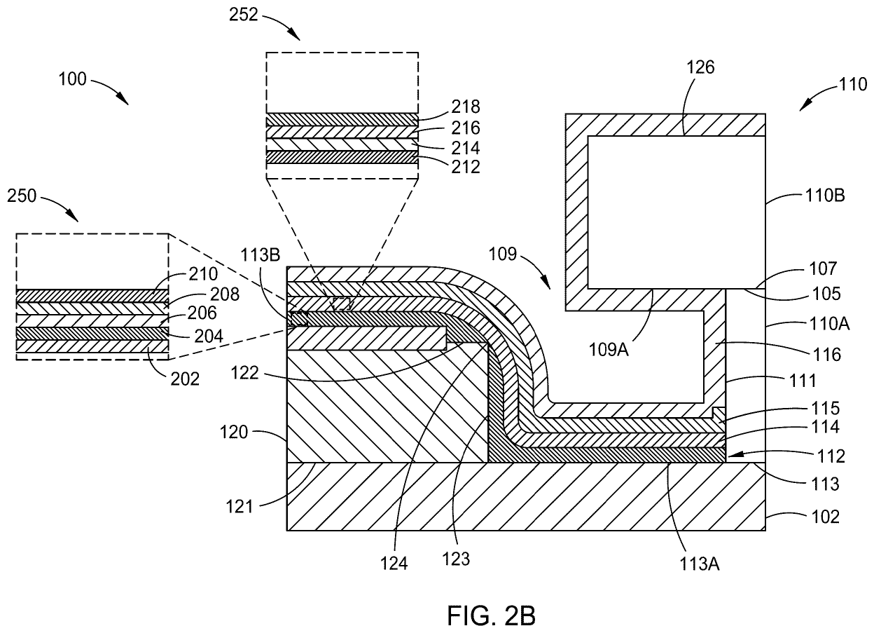

The adjacent overhangs 109 are defined by the overhang extension 109A. At least a bottom surface 107 of the second structure 110B is wider than the upper surface 105 of the first structure 110A to form the overhang extension 109A. The overhang extension 109A of the adjacent second structures 110B forms the adjacent overhangs 109 and allows for the second structure 110B to shadow the first structure 110A. The shadowing of the adjacent overhangs 109 provides for evaporation deposition of an OLED material 112 and a cathode 115. The OLED material 112 and the cathode 115 extend across each sub-pixel line in the line plane, as shown in FIG. 1B. The OLED material 112 includes a choked portion 113 and a continuous portion 114. The OLED material 112 may include a single stack structure or a tandem stack structure. The single stack structure is shown in greater detail in FIG. 2A. The tandem stack structure is shown in greater detail in FIG. 2B. The OLED material 112 may include one or more of a HIL, a HTL, an EML, and an ETL.

The choked portion 113 includes one or more layers. At least on layer of the one or more layers includes a choked region 113A and a continuous region 113B. The choked portion 113 is disposed over the PIS 120 of each sub-pixel line. The continuous region 113B is disposed the anode 104 and extends over upper surface 122 of the PIS 120 to the sidewall 123 of the PIS 120. The choked region 113A extends along the sidewall 123 and under the adjacent overhangs 109 and may contact a sidewall 111 of the first structure 110A. A separation edge 124 of the PIS 120 separates the continuous region 113B from the choked region 113A. In one or more embodiments, the choked region 113A and the continuous region 113B are electrically separated so that a current conducted through the anode 104 is prevented being conducted to the choked region 113A of the choked portion 113. The choked region 113A acts as a protective layer between the substrate 102 and the cathode. In one or more embodiments, the choked region 113A and the continuous region 113B are physically continuous and electrically separated. In one or more embodiments, the choked region 113A and the continuous region 113B are physically separated and electrically separated. The choked portion 113 extends across the sub-pixel line in the line plane as shown in FIG. 1B.

The continuous portion 114 is disposed over the choked portion 113. The continuous portion 114 extends across both the continuous region 113B and the choked region 113A of the choked portion 113. The choked portion 113 forms a smooth profile over the PIS 120. The smooth profile of the choked portion 113 allows the continuous portion 114 to be deposited continuously without being electrically or physically separated. The continuous portion 114 extends across the sub-pixel line in the line plane as shown in FIG. 1B.

OLED material 112 is disposed under adjacent overhangs 109 and may contact a sidewall 111 of the first structure 110A. In one embodiment, the OLED material 112 is different from the material of the first structure 110A and the second structure 110B. The cathode 115 is disposed over the OLED material 112 and extends under the adjacent overhangs 109. The choked portion 113 and the continuous portion 114 of the OLED material 112 form a smooth profile over the PIS 120. The smooth profile of the OLED material 112 allows the cathode 115 to be continuous over the OLED material 112 without being electrically or physically separated. The choked region 113A acts as a barrier layer between the substrate 102 and a cathode 115. The cathode 115 may extend past an endpoint of the OLED material 112. The cathode 115 contacts the sidewall 111 of the first structure 110A. The first structure 110A as acts the global cathode contact for the sub-pixel circuit 100. The overhang structures 110 and an evaporation angle set by an evaporation source define deposition angles, i.e., the overhang structures provide for a shadowing effect during evaporation deposition with the evaporation angle set by the evaporation source.

The cathode 115 includes a conductive material, such as a metal. E.g., the cathode 115 includes, but is not limited to, silver, magnesium, chromium, titanium, silicon, aluminum, ITO, or a combination thereof. In one embodiment, material of the cathode 115 is different from the material of the first structure 110A and the second structure 110B. The cathode 115 extends across the sub-pixel line in the line plane as shown in FIG. 1B.

Each sub-pixel includes an encapsulation layer 116. The encapsulation layer 116 may be or may correspond to a local passivation layer. The encapsulation layer 116 of a respective sub-pixel is disposed over the cathode 115 (and OLED material 112) with the encapsulation layer 116 extending under at least a portion of each of the adjacent overhangs 109 and along a sidewall 111 of each of the first structure 110A and the second structure 110B. The encapsulation layer 116 is disposed over the cathode 115 and extends at least to contact the cathode 115 over the sidewall 111 of the first structure 110A in the pixel plane. In some embodiments, the encapsulation layer 116 extends to contact the sidewall 111 of the first structure 110A. In the illustrated embodiments as shown in FIGS. 1A and 1B, the encapsulation layer 116 extends to contact the second structure 110B at an underside surface of the overhang extension 109A, the sidewall 117 of a second structure 110B, and an upper surface 118 of the second structure 110B. In some embodiments, the encapsulation layer 116 extends to contact the second structure 110B at an underside surface of the overhang extension 109A and to be disposed over the OLED material 112 and the cathode 115 when the OLED material 112 and the cathode 115 are disposed over the sidewall 111 and an upper surface 126 of the second structure 110B. The encapsulation layer 116 includes the non-conductive inorganic material, such as the silicon-containing material. The silicon-containing material may include silicon nitride (SiNₓ), silicon oxide (SiO₂), and silicon oxynitride (SiON) materials. In another embodiment, the sub-pixel circuit 100 further includes at least a global passivation layer disposed over the overhang structure 110 and the encapsulation layer 116. The encapsulation layer 116 extends across the sub-pixel line in the line plane as shown in FIG. 1B.

FIG. 1C is a schematic, cross-sectional top view of the sub-pixel circuit 100. The sub-pixel circuit 100 includes a plurality of pixel openings 127. Each of pixel opening 127 is abutted by overhang structures 110 in the pixel plane, as shown in FIG. 1A, which define each of the sub-pixel line. It is contemplated that although FIG. 1C does not show the OLED material 112, the cathode 115, or the encapsulation layer 116, it is understood that this is done for illustrative purposes.

FIG. 2A is a close-up schematic, cross-sectional view of a sub-pixel circuit 100 having a single stack structure. Section A of FIG. 2A is a close up schematic cross-section of a portion of the choked portion 113 of the OLED material 112 having a single stack structure. The choked portion 113 of the OLED material 112 having a single stack structure includes a hole inject layer (HIL) 202 and a hole transport layer (HTL) 204. The choked portion 113 may also include a prime layer. Section B of FIG. 2A is a close up schematic cross-section of a portion of the continuous portion 114 of the OLED material 112 having a single stack structure. The continuous portion 114 of the OLED material 112 having a single stack structure includes an emission material layer (EML) 206 and an electron injection layer (EIL) 208. It is contemplated that the continuously layer can include additional layers such as the electron transport layer (ETL).

FIG. 2B is a close-up schematic, cross-sectional view of a sub-pixel circuit 100 having a tandem stack structure. A tandem stack structure includes two or more single stack structures deposited over one another with a charge generation layer (CGL) deposited between each stack. Section C of FIG. 2B is a close up schematic cross-section of a portion of the choked portion 113 of the OLED material 112 having a tandem stack structure. The choked portion 113 of the OLED material 112 having a tandem stack structure includes a first stack 250. The first stack includes a HIL 202, a HTL 204, an EML 206, an EIL 208, and a CGL 210. Section D of FIG. 2B is a close up schematic cross-section of a portion of the continuous portion 114 of the OLED material 112 having a tandem stack structure. The continuous portion 114 of the OLED material 112 having a tandem stack structure includes a second stack 252. The second stack 252 includes a second HIL 212, a second HTL 214, a second EML 216, and a second EIL 218. It is contemplated that the continuously layer can include additional layers such as the electron transport layer (ETL). Although FIG. 2B shows the OLED material 112 having a tandem stack structure including two stacks, the continuous portion 114 including one stack. It is contemplated that the continuous portion 114 of the OLED material 112 can include additional stacks including but not limited to two stacks, three stacks, or four stacks.

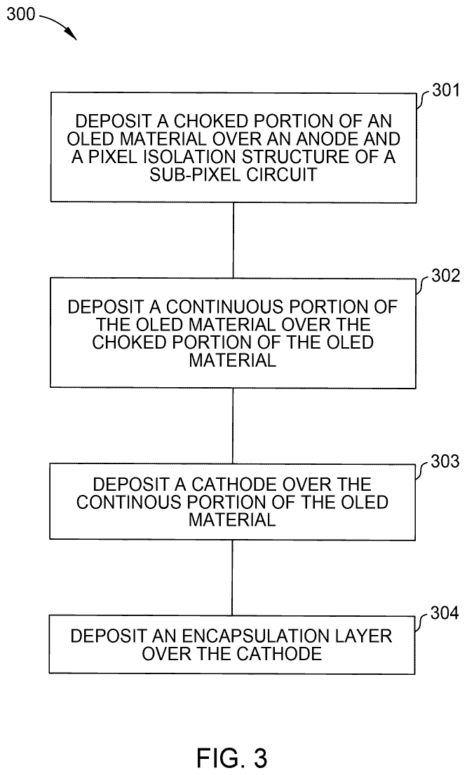

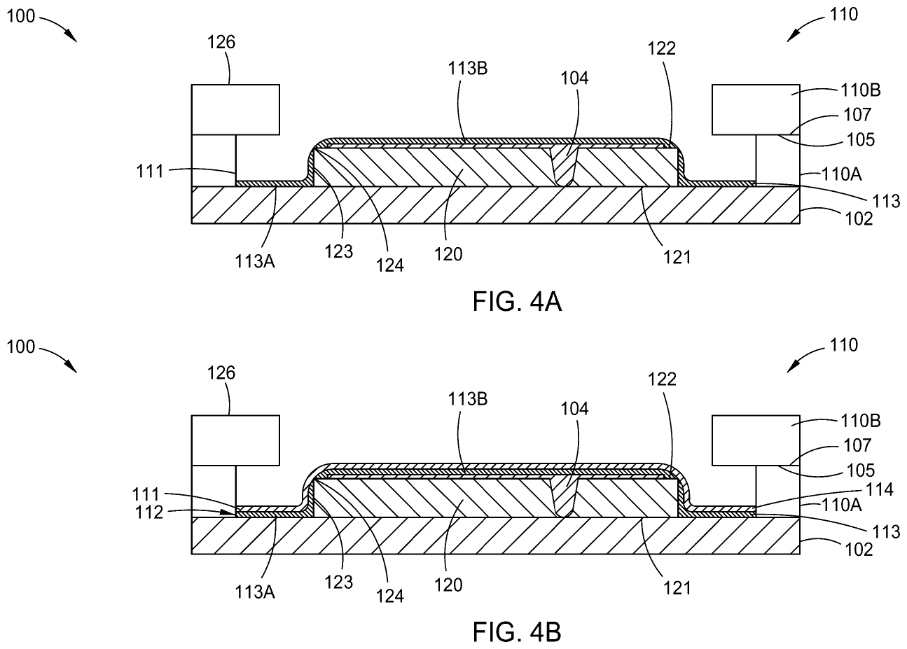

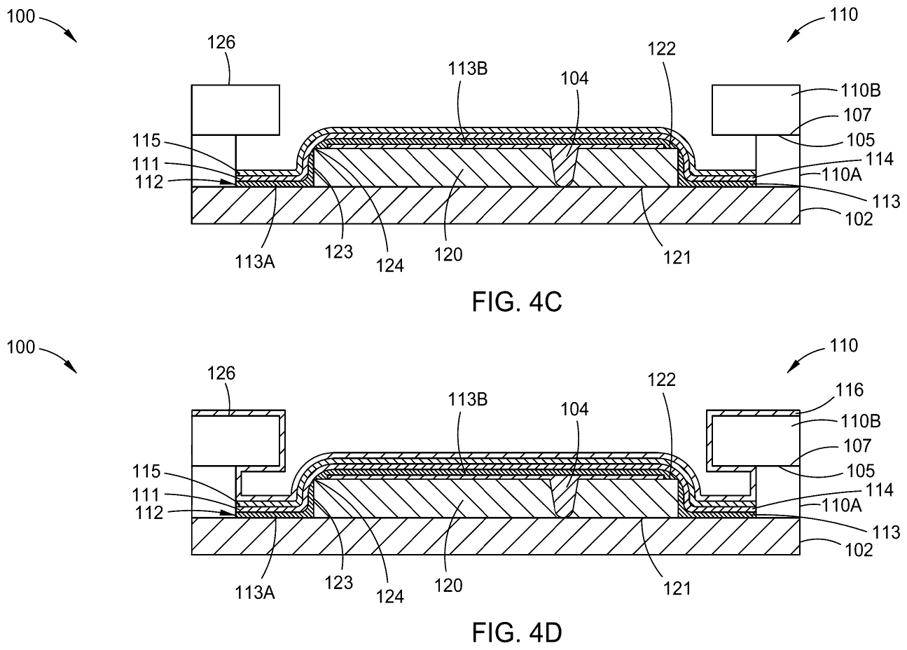

FIG. 3 is a flow diagram of a method 300 for forming the sub-pixel circuit 100. FIG. 4A-4D are schematic, cross-sectional views of a substrate 102 during a method 300 for forming a sub-pixel circuit 100, according to one or more embodiments.

At operation 301, as shown in FIG. 4A (along the pixel plane), a choked portion 113 of the OLED material 112 is deposited over the anode 104 and the PIS 120. The choked portion 113 includes a plurality of layers used to form the OLED material 112. If the OLED material 112 is a single stack structure, the choked portion 113 may a HIL 202 and an HTL 204 as described in FIG. 2A. The choked portion 113 may further include a prime layer if needed. If the OLED material 112 is a tandem stack structure, the choked portion 113 may a HIL 202, HTL 204, an EML 206, an EIL 208, and a CGL 210 as described in FIG. 2B. The layers described above that make up the choked portion 113 of the OLED material 112 are deposited during a deposition process. The choked portion 113 is deposited over the anode 104 and upper surface 122 of the PIS 120. The choked portion 113 extends to the separation edge 124 of the PIS 120. The choked portion 113 is further deposited past the separation edge along the sidewall 123 of the PIS 120. The choked portion 113 is further deposited over the substrate 102 below the adjacent overhangs 109 of the overhang structures 110. The separation edge 124 electrically separates the chocked portion 113 into the choked region 113A and the continuous region 113B. In one or more embodiments the choked region 113A and the continuous region 113B are electrically separated but physically connected. In one or more embodiments, the choked region 113A and the continuous region 113B are both electrically separated and physically separated by the separation edge 124. The choked region 113A acts as a barrier layer, such as an electrical barrier, between the substrate 102 and the cathode 115.

At operation 302, as shown in FIG. 4B (along the pixel plane), a continuous portion 114 of the OLED material 112 is deposited on the choked portion 113 of the OLED material 112. The continuous portion 114 includes a plurality of layers used to form the OLED material 112. If the OLED material 112 is a single stack structure, the continuous portion 114 may an EML 206 and an EIL 208 as described in FIG. 2A. If the OLED material 112 is a tandem stack structure, the continuous portion 114 include a second stack 252 deposited over the first stack 250 of the choked portion 113 as described in FIG. 2B. The second stack 252 may include a second HIL 212, a second HTL 214, a second EML 216, and a second EIL 218, as described in FIG. 2B. It is contemplated that the continuous portion 114 of the OLED material 112 with a tandem stack structure may include additional stacks. The layers described above that make up the continuous portion 114 of the OLED material 112 are deposited during a deposition process. The continuous portion 114 is deposited over the choked portion 113 to form the OLED material 112. The continuous portion 114 extends across both the choked regions 113A and the continuous region 113B of the choked portion 113. The choked portion 113 forms a smooth profile over the PIS 120. The smooth profile of the choked portion 113 allows the continuous portion 114 to be deposited continuously without being electrically or physically separated.

At operation 303, as shown in FIG. 4C (along the pixel plane), a cathode 115 is deposited over the continuous portion 114 of the OLED material 112. The cathode 115 extends across both the choked regions 113A and the continuous region 113B of the choked portion 113. The OLED material 112 forms a smooth profile over the PIS 120. The smooth profile of the OLED material 112 allows the cathode 115 to be deposited continuously without being electrically or physically separated. The cathode 115 is formed of a silver (Ag) or magnesium (Mg) alloy. The cathode extends over the OLED material 112, under the adjacent overhangs 109, and contacts the sidewall 111 of the first structure 110A. The first structure 110A as acts the global cathode contact for the sub-pixel circuit 100.

At operation 304, as shown in FIG. 4D (along the pixel plane), an encapsulation layer 116 is deposited over the cathode 115 and the overhang structures 110. The encapsulation layer 116 is disposed over the cathode 115 and extends at least to contact the cathode 115 over the sidewall 111 of the first structure 110A in the pixel plane. In some embodiments, the encapsulation layer 116 extends to contact the sidewall 111 of the first structure 110A. In the illustrated embodiments as shown in FIGS. 1A and 1B, the encapsulation layer 116 extends to contact the second structure 110B at an underside surface of the overhang extension 109A, the sidewall 117 of a second structure 110B, and an upper surface 118 of the second structure 110B. In some embodiments, the encapsulation layer 116 extends to contact the second structure 110B at an underside surface of the overhang extension 109A and to be disposed over the OLED material 112 and the cathode 115 when the OLED material 112 and the cathode 115 are disposed over the sidewall 111 and upper surface 126 of the second structure 110B. In another embodiment, the sub-pixel circuit 100 further includes at least a global passivation layer disposed over the overhang structure 110 and the encapsulation layer 116. The encapsulation layer 116 extends across the sub-pixel line in the line plane as shown in FIG. 1B.

Benefits of the present disclosure include a sub-pixel circuit having global cathode contact. The PIS 120 having an increased thickness allows for a portion of the OLED material 112 to be choked. This choked portion 113 of the OLED material acts a as a barrier layer between the substrate 102 and the cathode 115. The choked portion 113 allows for the cathode 115 to contact the sidewall 111 of first structure 110A of the overhang structure 110. The first structure 110A is formed of a conductive material and acts as a global cathode contact for the sub-pixel circuit 100. In general, the sub-pixel architecture described herein allows for an increased deposition tolerance for both the OLED material 112 and the cathode 115. The portion of the cathode 115 that contacts the sidewall 111 has an increased tolerance as the choked portion 113 acts as a barrier between the cathode 115 and the substrate 102. Additionally, the deposition angles of the OLED material 112 and the cathode 115 can be greater as less deposition control is necessary. The device and method of forming the device described herein allows for the manufacturing of a sub-pixel circuit without a local cathode contact, which drastically decreases the manufacturing cost of large OLED devices.

It is contemplated that one or more aspects disclosed herein may be combined. As an example, one or more aspects, features, components, operations and/or properties of the sub-pixel circuit 100, the substrate 102, the anode 104, the PIS 120, the OLED material 112, the choked portion 113, the continuous portion 114, the cathode 115, the encapsulation layer 116, the overhang structures 110, the first structure 110A, the second structure 110B, the opening 125, the first stack 250, the second stack 252, the HIL 202, the HTL 204, the EML 206, the EIL 208, the CGL 210, the second HIL 212, the second HTL 214, the second EML, the second EIL, and/or method 300 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A sub-pixel, comprising:
adjacent overhang structures disposed over a substrate, each overhang structure having an overhang extension extending laterally past a sidewall of each overhang structure;
a pixel isolation structure (PIS) disposed over the substrate between the adjacent overhang structures, the PIS comprising an upper surface and at least two sidewalls opposing each other;
an anode disposed on the PIS; and
an OLED material disposed over the anode and extending over the upper surface and the sidewalls of the PIS, the OLED material further extending under the overhang extension, the OLED material comprising:
a choked portion having one or more layers, at least one layer of the one or more layers comprising:
a continuous region disposed over the anode and the upper surface of the PIS; and
a choked region disposed over the sidewalls and extending under the overhang extension, wherein the choked region and the continuous region of the at least one layer are electrically separated from one another;
a continuous portion disposed over the choked portion; and
a cathode disposed over the OLED material.

2. The sub-pixel of claim 1, wherein a layer of the one or more layers of the choked portion comprises:
a hole inject layer; or
a hole transport layer disposed over the hole inject layer.

3. The sub-pixel of claim 2, wherein the continuous portion comprises:
an emission material layer; and
an electron injection layer disposed over the emission material layer.

4. The sub-pixel of claim 1, wherein a layer of the one or more layers of the choked portion comprises:
a first hole inject layer;
a first hole transport layer disposed over the first hole inject layer;
a first emission material layer disposed over the first hole transport layer;
a first electron injection layer disposed over the first emission material layer; or
a charge generation layer disposed over the first electron injection layer.

5. The sub-pixel of claim 4, wherein the continuous portion comprises:
a second hole inject layer;
a second hole transport layer disposed over the second hole inject layer;
a second emission material layer disposed over the second hole transport layer; and
a second electron injection layer disposed over the second emission material layer.

6. The sub-pixel of claim 1, wherein the PIS has a height from about 200 nm to about 300 nm.

7. The sub-pixel of claim 1, wherein at least a portion the OLED material contacts the sidewall of each of the adjacent overhang structures.

8. The sub-pixel of claim 1, wherein at least a portion the cathode contacts the sidewall of each of the adjacent overhang structures.

9. The sub-pixel of claim 1, wherein the PIS further comprises an opening extending from the upper surface of the PIS to a lower surface of the PIS.

10. The sub-pixel of claim 9, wherein the at least a portion of the anode is deposited within the opening.

11. A sub-pixel, comprising:
adjacent overhang structures disposed on a substrate along a line plane, the adjacent overhang structures comprising:
a first structure disposed on the substrate; and
a second structure disposed on the first structure, wherein a bottom surface of the second structure extends laterally past an upper surface of the first structure defining an overhang extension;
a pixel isolation structure (PIS) disposed on the substrate extending along the line plane in between the adjacent overhang structures, the PIS comprising an upper surface and a plurality of sidewalls;
an anode disposed on the PIS;
an OLED material disposed over the anode and extending over the upper surface and the plurality of sidewalls of the PIS, the OLED material further extending under the overhang extension, the OLED material comprising:
a choked portion, the choked portion comprising:
a continuous region disposed over the anode and the upper surface of the PIS; and
a choked region disposed over the plurality of sidewalls and extending under the overhang extension, wherein the choked region and the continuous region are electrically separated from one another;
a continuous portion disposed over the choked portion; and
a cathode disposed over the OLED material.

12. The sub-pixel of claim 11, wherein the choked portion comprises:
a hole inject layer; and
a hole transport layer disposed over the hole inject layer.

13. The sub-pixel of claim 12, wherein the continuous portion comprises:
an emission material layer; and
an electron injection layer disposed over the emission material layer.

14. The sub-pixel of claim 11, wherein the choked portion comprises:
a first hole inject layer;
a first hole transport layer disposed over the first hole inject layer;
a first emission material layer disposed over the first hole transport layer;
a first electron injection layer disposed over the first emission material layer; and
a charge generation layer disposed over the first electron injection layer.

15. The sub-pixel of claim 14, wherein the continuous portion comprises:
a second hole inject layer;
a second hole transport layer disposed over the second hole inject layer;
a second emission material layer disposed over the second hole transport layer; and
a second electron injection layer disposed over the second emission material layer.

16. The sub-pixel of claim 11, wherein the PIS has a height from about 200 nm to about 300 nm.

17. The sub-pixel of claim 11, wherein at least a portion the OLED material contacts the first structure of each of the adjacent overhang structures.

18. The sub-pixel of claim 11, wherein at least a portion the cathode contacts the first structure of each of the adjacent overhang structures.

19. The sub-pixel of claim 11, wherein the PIS further comprises an opening extending from the upper surface of the PIS to a lower surface of the PIS and at least a portion of the anode is deposited within the opening.

20. A device, comprising:
a plurality of sub-pixel lines, each sub-pixel line comprising at least at least one sub-pixel, the at least one sub-pixel comprising:
adjacent overhang structures disposed on a substrate along a line plane, the adjacent overhang structures comprising:
a first structure disposed on the substrate; and
a second structure disposed on the first structure, wherein a bottom surface of the second structure extends laterally past an upper surface of the first structure defining an overhang extension;
a pixel isolation structure (PIS) disposed on the substrate extending along the line plane in between the adjacent overhang structures, the PIS comprising an upper surface and a plurality of sidewalls;
an anode disposed on the PIS;
an OLED material disposed over the anode and extending over the upper surface and the plurality of sidewalls of the PIS, the OLED material further extending under the overhang extension, the OLED material comprising:
a choked portion, the choked portion comprising:
a continuous region disposed over the anode and the upper surface of the PIS; and
a choked region disposed over the plurality of sidewalls and extending under the overhang extension, wherein the choked region and the continuous region are electrically separated from one another;
a continuous portion disposed over the choked portion;
a cathode disposed over the OLED material; and
an encapsulation layer disposed over the cathode.
